(19) United States
(12) Patent Application Publication
(10) Pub. No.: US 2025/0081551 A1
(43) Pub. Date: Mar. 6, 2025

(54) 3D COMB NANOSHEET AND PI/2 ROTATED NANOSHEET

(71) Applicant: Tokyo Electron Limited, Tokyo (JP)

(72) Inventors: H. Jim FULFORD, Marianna, FL (US); Mark I. GARDNER, Cedar Creek, TX (US)

(73) Assignee: Tokyo Electron Limited, Tokyo (JP)

(21) Appl. No.: 18/458,630

(22) Filed: Aug. 30, 2023

(51) Int. Cl. H01L 29/06; H01L 21/8238; H01L 27/088; H01L 29/08; H01L 29/423; H01L 29/66; H01L 29/775; H01L 29/786

(52) U.S. Cl. CPC H10D 62/121; H10D 30/014; H10D 30/43; H10D 30/6735; H10D 30/6757; H10D 62/122; H10D 62/151; H10D 64/017; H10D 84/0167; H10D 84/017; H10D 84/0172; H10D 84/038; H10D 84/83

(57) ABSTRACT

A semiconductor device is provided. The semiconductor device includes a substrate and channel structures stacked over each other along a first direction substantially perpendicular to a working surface of the substrate and each configured to have a current direction along a second direction substantially parallel to the working surface of the substrate. Source/drain (S/D) structures are positioned on opposing sides of the channel structure along the second direction. Gate structures are positioned on opposite sides of the channel structures along a third direction substantially parallel to the working surface of the substrate. The channel structures each have a shape of a nanosheet extending substantially perpendicular to the working surface of the substrate.

### FIELD OF THE INVENTION

This disclosure relates to microelectronic devices including semiconductor devices, transistors, and integrated circuits, and methods of microfabrication.

### BACKGROUND

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Historically, with microfabrication, transistors have been created in one plane, with wiring/metallization formed above the active device plane, and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes. Semiconductor device fabricators have expressed a desire for three-dimensional (3D) semiconductor circuits in which transistors are stacked on top of each other.

### SUMMARY

The present disclosure relates to a semiconductor device and a method of forming the semiconductor device.

According to a first aspect of the disclosure, a semiconductor device is provided. The semiconductor device includes a substrate and channel structures stacked over each other along a first direction substantially perpendicular to a working surface of the substrate and each configured to have a current direction along a second direction substantially parallel to the working surface of the substrate. Source/drain (S/D) structures are positioned on opposing sides of the channel structure along the second direction. Gate structures are positioned on opposite sides of the channel structures along a third direction substantially parallel to the working surface of the substrate. The channel structures each have a shape of a nanosheet extending substantially perpendicular to the working surface of the substrate.

In some embodiments, the nanosheet has a first dimension of 1-15 nm in the first direction. The nanosheet has a second dimension of 1-15 nm in the second direction, and the nanosheet has a third dimension of 0.1-3.0 nm in the third direction.

In some embodiments, a first ratio of the third dimension to the first dimension is 0.05-0.3, and a second ratio of the third dimension to the second dimension is 0.05-0.3.

In some embodiments, the channel structures comprise epitaxially grown semiconductor material.

In some embodiments, the channel structures are separated from each other only by dielectric material and not by metal material in the first direction.

In some embodiments, the gate structures include two separate gate structures on the opposite sides of the channel structures along the third direction.

In some embodiments, the two separate gate structures each are configured to be electrically connected to the channel structures.

In some embodiments, the substrate has a top surface of monocrystalline semiconductor material.

According to a second aspect of the disclosure, a method of manufacturing a semiconductor device is provided. The method includes forming channel structures over a substrate. The channel structures are stacked over each other along a first direction substantially perpendicular to a working surface of the substrate and each configured to have a current direction along a second direction substantially parallel to the working surface of the substrate. The channel structures each have a shape of a nanosheet extending substantially perpendicular to the working surface of the substrate. Source/drain (S/D) structures are formed on opposing sides of the channel structure along the second direction. Gate structures are formed on opposite sides of the channel structures along a third direction substantially parallel to the working surface of the substrate.

In some embodiments, a layer stack is formed over the substrate. The layer stack includes dielectric layers and sacrificial layers alternatingly stacked over each other. The sacrificial layers are directionally etched to form individual nanosheets that are spaced apart from one another in the third direction and extend substantially perpendicular to the working surface of the substrate.

In some embodiments, an epitaxial seed structure is formed that extends through the layer stack from the substrate. The individual nanosheets are removed to uncover side portions of the epitaxial seed structure. Semiconductor material is epitaxially grown from the side portions of the epitaxial seed structure to form the channel structures.

In some embodiments, the substrate has a top surface including monocrystalline semiconductor material.

In some embodiments, an opening is formed through the layer stack. The opening uncovers the top surface of the substrate. The epitaxial seed structure is epitaxially grown from the top surface of the substrate to fill the opening.

In some embodiments, an opening is formed in the layer stack. The opening uncovers side portions of the individual nanosheets. The individual nanosheets are selectively etched to form gaps between neighboring dielectric layers. The gaps uncover the side portions of the epitaxial seed structure. The gaps are filled with the semiconductor material.

In some embodiments, a first epitaxial seed structure and a second epitaxial seed structure are formed, both of which extend through the layer stack from the substrate. An opening is formed in the layer stack between the first epitaxial seed structure and the second epitaxial seed structure. The opening divides the individual nanosheets into first nanosheets and second nanosheets. The first nanosheets are replaced with a first semiconductor material connected to the first epitaxial seed structure. The second nanosheets ae replaced with a second semiconductor material connected to the second epitaxial seed structure.

According to a third aspect of the disclosure, a method of manufacturing a semiconductor device is provided. The method includes forming a layer stack over a substrate. The layer stack includes dielectric layers and sacrificial layers alternatingly stacked over each other. An epitaxial seed structure is formed that has a shape of comb handle extending through the layer stack from the substrate. The sacrificial layers are removed to uncover side portions of the epitaxial seed structure. Semiconductor material is epitaxially grown from the side portions of the epitaxial seed structure to form a comb-shaped epitaxial structure.

In some embodiments, the substrate has a top surface comprising monocrystalline semiconductor material.

In some embodiments, an opening is formed in the layer stack. The opening uncovers the top surface of the substrate. The epitaxial seed structure is epitaxially grown from the top surface of the substrate to fill the opening.

In some embodiments, an opening is formed in the layer stack. The opening uncovers side portions of the sacrificial layers. The sacrificial layers are selectively etched to form gaps between neighboring dielectric layers. The gaps uncover the side portions of the epitaxial seed structure. The gaps are filled with the semiconductor material.

In some embodiments, the epitaxially growing the semiconductor material from the side portions of the epitaxial seed structure includes epitaxially growing an epitaxial transition structure from the side portions of the epitaxial seed structure. The semiconductor material is epitaxially grown from the epitaxial transition structure.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be increased or reduced for clarity of discussion.

FIGS. 1A and 1B show vertical cross-sectional views of a semiconductor device, in accordance with some embodiments of the present disclosure.

FIG. 2 shows a flow chart of a process for manufacturing a semiconductor device, in accordance with one embodiment of the present disclosure.

FIG. 3 shows a flow chart of a process for manufacturing a semiconductor device, in accordance with another embodiment of the present disclosure.

FIGS. 4, 5, 6, 7, 8, 9 and 10 show cross-sectional views of a semiconductor device at various intermediate steps of manufacturing, in accordance with some embodiments of the present disclosure.

FIG. 6B shows a top-down view of the semiconductor device in FIG. 6 in accordance with one embodiment of the present disclosure.

FIG. 7B shows a vertical cross-sectional view taken along the line cut BB′ in FIG. 7 in accordance with one embodiment of the present disclosure.

FIG. 8B shows a vertical cross-sectional view taken along the line cut CC′ in FIG. 8 in accordance with one embodiment of the present disclosure.

FIGS. 11A and 11B show cross-sectional views of a semiconductor device at various intermediate steps of manufacturing, in accordance with some embodiments of the present disclosure.

FIGS. 12, 13, 14, 15, 16 and 17 show cross-sectional views of a semiconductor device at various intermediate steps of manufacturing, in accordance with some embodiments of the present disclosure.

FIG. 18 shows a vertical cross-sectional view of a semiconductor device, in accordance with some embodiments of the present disclosure.

FIGS. 19, 20, 21 and 22 show cross-sectional views of a semiconductor device at various intermediate steps of manufacturing, in accordance with some embodiments of the present disclosure.

FIGS. 23, 24, 25, 26, 27, 28, 29, 30, 31, 32, 33, 34, 35, 36, 37, 38, 39, 40, 41 and 42 show cross-sectional views of a semiconductor device at various intermediate steps of manufacturing, in accordance with some embodiments of the present disclosure.

FIG. 23B shows a top-down view of the semiconductor device in FIG. 23 in accordance with one embodiment of the present disclosure.

FIG. 24B shows a top-down view of the semiconductor device in FIG. 24 in accordance with one embodiment of the present disclosure.

FIG. 25B shows a vertical cross-sectional view taken along the line cut FF′ in FIG. 25 in accordance with one embodiment of the present disclosure.

FIG. 34B shows a top-down view of the semiconductor device in FIG. 34 in accordance with one embodiment of the present disclosure.

FIG. 37B shows a top-down view of the semiconductor device in FIG. 37 in accordance with one embodiment of the present disclosure.

FIG. 38B shows a top-down view of the semiconductor device in FIG. 38 in accordance with one embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

In the drawings, like reference numerals designate identical or corresponding parts throughout the several views. Additionally, as used herein, the words “a”, “an” and the like generally carry a meaning of “one or more”, unless stated otherwise.

Furthermore, the terms, “approximately”, “approximate”, “about” and similar terms generally refer to ranges that include the identified value within a margin of 20%, 10%, or preferably 5%, and any values therebetween.

3D integration, i.e. the vertical stacking of multiple devices, aims to overcome scaling limitations experienced in planar devices by increasing transistor density in volume rather than area. Although device stacking has been successfully demonstrated and implemented by the flash memory industry with the adoption of 3D NAND, application to random logic designs is substantially more difficult. 3D integration for logic chips (CPU (central processing unit), GPU (graphics processing unit), FPGA (field programmable gate array, SoC (System on a chip)) is being pursued.

Techniques herein utilize a concept of a comb nanosheet that uses an epitaxy tunnel technique that enables any epitaxial material to be selectively grown is a specific tunnel for optimum NMOS (negative channel metal oxide semiconductor) and PMOS (positive channel metal oxide semiconductor) high mobility devices. 3D nanosheets can be grown to higher N values since all silicon nanosheets are grown in parallel. Techniques herein also require fewer epitaxy steps and yet offer high-quality epitaxy.

Aspects of the present disclosure are related to 3D nanosheet formation, for example starting with a semiconductor seed region in an epitaxial tunnel (growing 3D stacked nanosheets) Si comb nanosheet, or starting with a semiconductor seed region in an epitaxial tunnel (growing 3D stacked nanosheets) Si comb nanosheet for NMOS and a SiGe seed layer for Ge comb nanosheet (side by side), or using an InGaAs channel by starting with a Si epitaxial seed in the epitaxial tunnel then growing the InGaAs channel in an epitaxial tunnel while utilizing an epitaxial transition layer in the epitaxial tunnel to enable a single crystal transition from silicon epitaxy to InGaAs epitaxy.

A conventional nanosheet extends or is oriented parallel to the substrate, and a gate structure is typically formed all around the nanosheet to form a gate-all-around (GAA) transistor structure. Techniques herein rotates a nanosheet by 90 degrees (i.e. p/2) so that the nanosheet extends or is oriented perpendicular to the substrate. As a result, the nanosheet may have a horizontal current flow in the two large-area vertical sides for large currents without using GAA.

A pi/2 rotated nanosheet (i.e. a 90-degree rotated nanosheet) enables a large current flow on the widest part of the nanosheet on both sides. Therefore, 3D stackable devices can be obtained. Techniques herein eliminate the need for a channel release. All epitaxially grown materials can be utilized for high mobility channels. Different S/D metals and gate electrode metals can be utilized for tuning work functions and device optimization. GAA device structure is not required because of the p/2 rotated nanosheet device. Such geometry provides essentially all the surface area of the device nanosheet for maximum Idsat and high-performance devices.

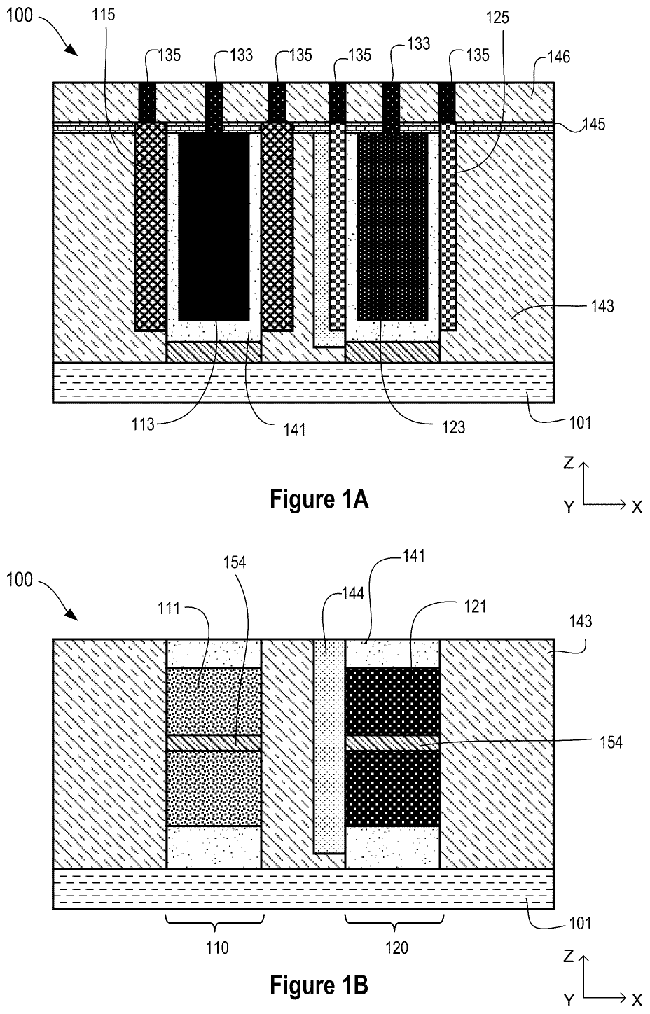

FIGS. 1A and 1B show vertical cross-sectional views of a semiconductor device 100, in accordance with some embodiments of the present disclosure. As shown, the semiconductor device 100 includes a first transistor 110 and a second transistor 120 over a substrate 101. Specifically, the first transistor 110 includes one or more (e.g. two) first channel structures 111, first S/D structures 115 and first gate structures 113 while the second transistor 120 includes one or more (e.g. two) second channel structures 121, second S/D structures 125 and second gate structures 123. Since the first transistor 110 is similar to the second transistor 120, descriptions below will be focused on the first transistor 110 for brevity purposes.

The first channel structures 111 can each have the shape of a nanosheet extending in the XZ plane or oriented perpendicular to the XY plane. The nanosheet can have a first dimension of 1-15 nm in the Z direction, a second dimension of 1-15 nm in the X direction, and a third dimension of 0.1-3.0 nm in the Y direction. A first ratio of the third dimension to the first dimension can be 0.01-0.30, e.g. 0.01, 0.05, 0.10, 0.12, 0.15, 0.18, 0.20, 0.25, 0.30, or any value therebetween. A second ratio of the third dimension to the second dimension can be 0.01-0.30, e.g. 0.01, 0.05, 0.10, 0.12, 0.15, 0.18, 0.20, 0.25, 0.30, or any value therebetween. That is to say, the nanosheet is relatively thin in the Y direction while extending in the XZ plane. Additionally, a third ratio of the first dimension to the second dimension can be 0.2-1.0, e.g. 0.2, 0.3, 0.4, 0.5, 0.6, 0.7, 0.8, 0.9 1.0, or any value therebetween.

Particularly, the first dimension can be 1 nm, 2 nm, 3 nm, 4 nm, 5 nm, 6 nm, 7 nm, 8 nm, 9 nm, 10 nm, 11 nm, 12 nm, 13 nm, 14 nm, 15 nm or any value therebetween. The second dimension can be 1 nm, 2 nm, 3 nm, 4 nm, 5 nm, 6 nm, 7 nm, 8 nm, 9 nm, 10 nm, 11 nm, 12 nm, 13 nm, 14 nm, 15 nm or any value therebetween. The third dimension can be 0.1 nm, 0.2 nm, 0.3 nm, 0.4 nm, 0.5 nm, 0.6 nm, 0.7 nm, 0.8 nm, 0.9 nm, 1.0 nm, 1.1 nm, 1.2 nm, 1.3 nm, 1.4 nm, 1.5 nm, 1.6 nm, 1.7 nm, 1.8 nm, 1.9 nm, 2.0 nm, 2.1 nm, 2.2 nm, 2.3 nm, 2.4 nm, 2.5 nm, 2.6 nm, 2.7 nm, 2.8 nm, 2.9 nm, 3.0 nm or any value therebetween.

In conventional technology, a nanosheet typically extends horizontally. That is, a conventional nanosheet has a smallest dimension in a vertical direction perpendicular to a working surface of a substrate. By contrast in the present disclosure, the nanosheet is a vertical nanosheet or a Pi/2 rotated nanosheet. That is, the first channel structures 111 each have a smallest dimension in the Y direction, instead of in the Z direction. As a result, a large current flow can be achieved on both sides of the nanosheet, thus eliminating the need for GAA transistor structure. Additionally, in some conventional examples, a semiconductor bar, wire or rod may be formed to function as a channel. However, a conventional semiconductor bar, wire or rod is different from the nanosheet described herein and cannot achieve the same advantage of having a large current flow on both sides.

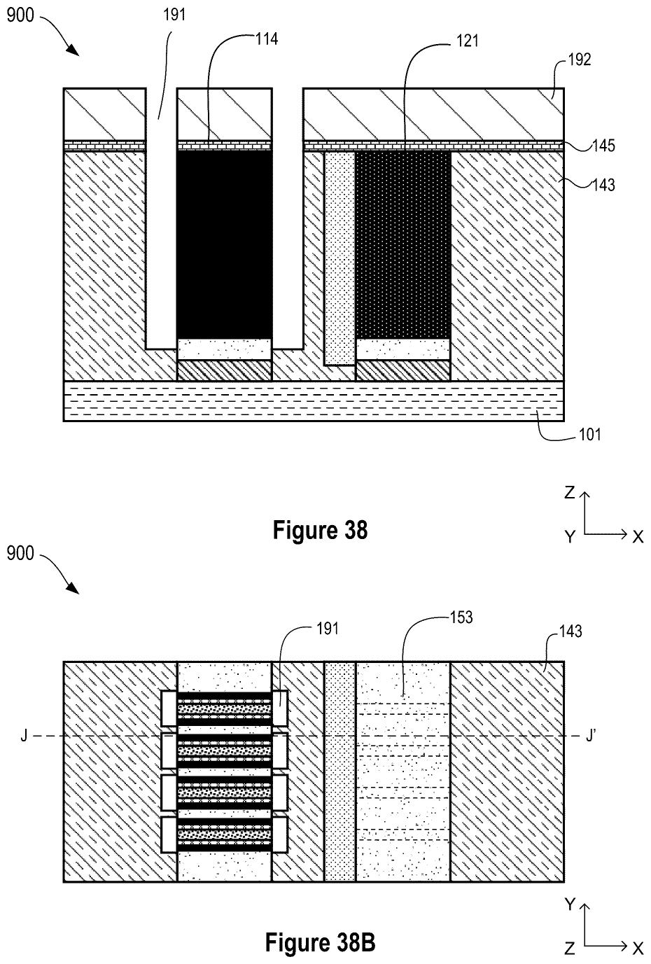

Herein, the cross-sectional view of Figure TA and the cross-sectional view of FIG. 1B are parallel to each other. The cross-sectional view of Figure TA can be in front of or behind the cross-sectional view of FIG. 1B. Therefore, the first transistor 110 can include two of the first gate structures 113, one in front of and the other behind the first channel structures 111 in the Y direction. While the first S/D structures 115 are omitted from FIG. 1B, it should be understood that the first S/D structures 115 exist in FIG. 1B and are in direct contact with both of the first channel structures 111, which will be further explained in FIGS. 38-40. Therefore, each of the first S/D structures 115 is configured to function as a common S/D structure for the first channel structures 111. The semiconductor device 100 can include contact structures 135 connected to the first S/D structures 115.

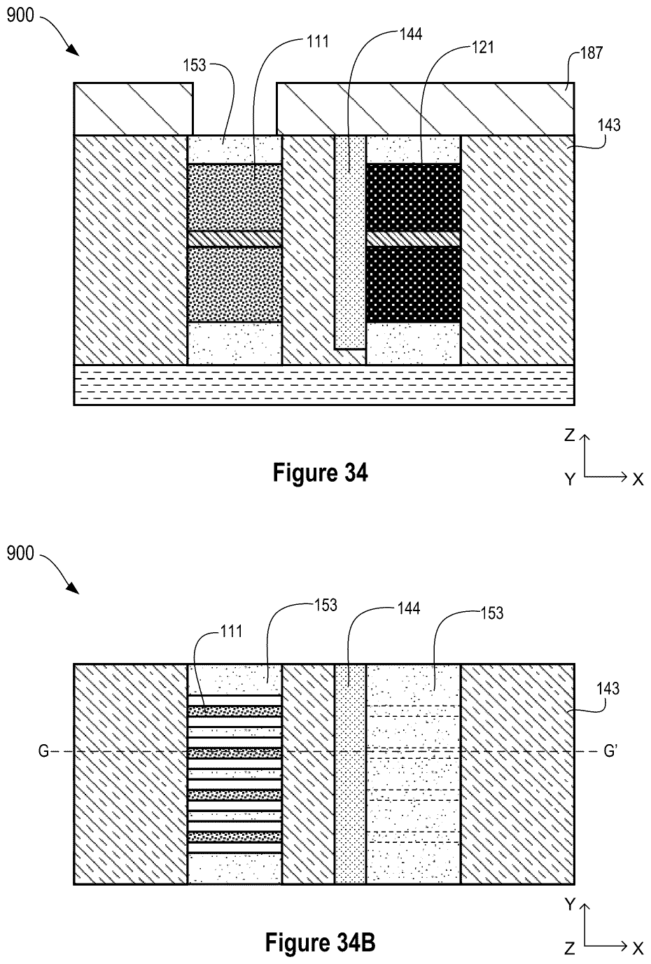

Each of the first gate structures 113 is also in direct contact with both of the first channel structures 111 and configured to function as a common gate structure. In the example of FIG. 1B, the first channel structures 111 are separated from each other only by dielectric material 154 and not by metal material in the Z direction. That is to say, the first gate structures 113 do not surround the first channel structures 111 from 360 degrees, therefore not forming GAA structure. As will be further explained in detail later in FIG. 34-37, the first gate structures 113 can include two separate gate structures that are not connected to each other but instead disposed on opposite sides of the first channel structures 111 in the Y direction. The semiconductor device 100 can include contact structures 133 connected to the first gate structures 113.

Note that at least two channel structures can include different chemical compositions from one another. That is, the channel structures can include different semiconductor materials, different dopants and/or different dopant concentration profiles. For instance, the first channel structures 111 stacked in the Z direction may include different chemical compositions from each other. The first channel structures 111 may include a different chemical composition from the second channel structures 121. In one example, the first channel structures 111 include <100> silicon while the second channel structures 121 include <110> silicon. In another embodiment, the first channel structures 111 include silicon (Si) while the second channel structures 121 include silicon germanium (SiGe). Alternatively, at least two channel structures can include a same chemical composition. For instance, the first channel structures 111 and the second channel structures 121 can both include p-doped silicon or both include n-doped silicon.

The first channel structures 111 and the second channel structures 121 can include epitaxially grown semiconductor material. “Epitaxial growth”, “epitaxial deposition”, “epitaxially grown”, “epitaxially formed” or “epitaxy” as used herein generally refers to a type of crystal growth or material deposition in which a crystalline layer is formed over a seed layer that is crystalline. Crystalline characteristics (e.g. crystal orientation) of the crystalline layer are related to or dictated by crystalline characteristics of the seed layer. Particularly, a semiconductor material can be epitaxially grown on a surface of another semiconductor layer that is crystalline. In some embodiments, epitaxial growth can be selective such that a semiconductor material may only be epitaxially grown on another semiconductor surface and generally do not deposit on exposed surfaces of non-semiconductor materials, such as silicon oxide, silicon nitride, and the like. Epitaxial growth can be accomplished by molecular beam epitaxy, vapor-phase epitaxy, liquid-phase epitaxy, or the like. Si, SiGe, Ge, InGaAs and other semiconductor materials can be doped during epitaxial growth (in situ) by addition of dopants. For example in vapor-phase epitaxy, a dopant vapor can be added to the gas source.

In the example of FIG. 1B, the first S/D structures 115 and the second S/D structures 125 are configured to electrically connect to a plurality of (e.g. two) channel structures. In alternative embodiments, the first S/D structures 115 and/or the second S/D structures 125 may be in direct contact with only one respective channel structure. Accordingly, the semiconductor device 100 can include single-channel transistors stacked in the Z direction.

Additionally, the substrate 101 can include a semiconductor material. In some embodiments, the substrate 101 is positioned over an insulator disposed on another substrate (not shown). That is, an epitaxial layer of the semiconductor material is grown on a substrate having a dielectric layer disposed thereon, i.e. an SOI (silicon-on-insulator), a GeOI (Germanium-on-insulator), an SGOI (SiGe-on-insulator) or the like. In some embodiments, the substrate 101 can include completed devices with isolated silicon on top. In some embodiments, the substrate 101 has a top surface of monocrystalline semiconductor material such as single crystal silicon. The single crystal silicon can function as a seed layer for epitaxially growing a semiconductor layer thereon.

The semiconductor device 100 can further include dielectric materials, e.g. as shown by 141, 143, 144, 145, 146 and 154. The dielectric materials may also be referred to as isolation structures, isolation layers, diffusion breaks, inner spacers, gate dielectrics, capping layers, etc. depending on functions thereof. For example, the dielectric material 154 can be used to separate the first channel structures 111 from each other and thus be referred to as an isolation structure or a diffusion break. The dielectric material 141 can separate the first gate structure 113 from the first S/D structures 115 and thus be referred to as an inner spacer. The dielectric material 141 can cover the first transistor 110 from above and thus also be referred to as a capping layer. Additionally, some of the dielectric materials may include identical materials or may include different materials. For example, the dielectric materials 141 and 152 may include a same material.

Of course it should be understood that the semiconductor device 100 can include any number of transistors, such as the first transistor 110, the second transistor 120 and the like, arranged in the XY plane over the substrate 101. The first transistor 110 can include any number of the first channel structures 111 arranged in the Z direction.

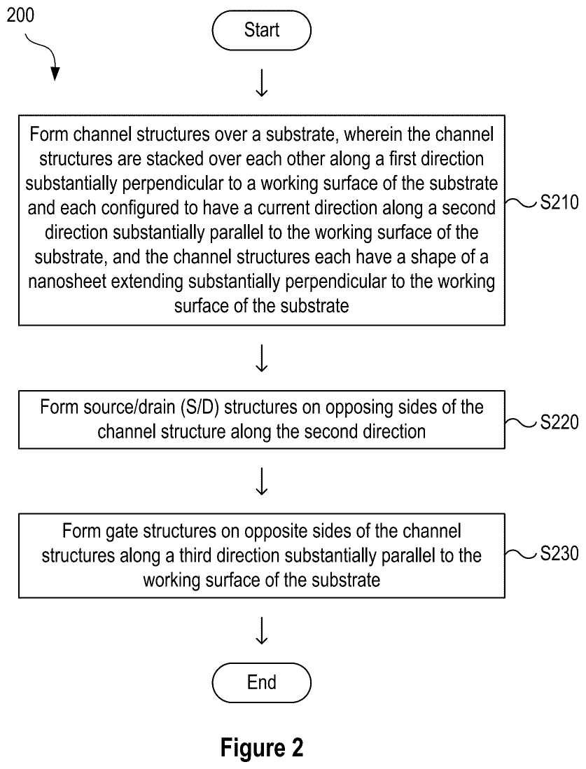

FIG. 2 shows a flow chart of a process 200 for manufacturing a semiconductor device (e.g. the semiconductor device 100), in accordance with one embodiment of the present disclosure. At Step S210, channel structures are formed over a substrate. The channel structures are stacked over each other along a first direction substantially perpendicular to a working surface of the substrate and each configured to have a current direction along a second direction substantially parallel to the working surface of the substrate. The channel structures each have a shape of a nanosheet extending substantially perpendicular to the working surface of the substrate. At Step S220, source/drain (S/D) structures are formed on opposing sides of the channel structure along the second direction. At Step S230, gate structures are formed on opposite sides of the channel structures along a third direction substantially parallel to the working surface of the substrate.

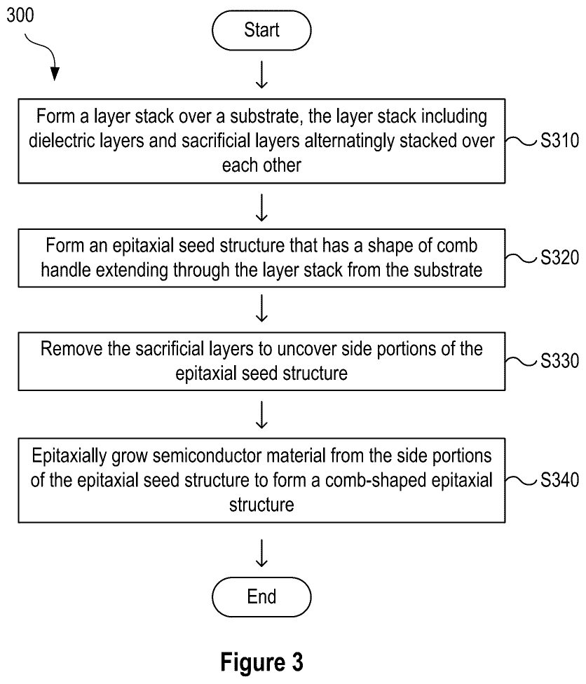

FIG. 3 shows a flow chart of a process 300 for manufacturing a semiconductor device, in accordance with another embodiment of the present disclosure. At Step S310, a layer stack is formed over a substrate. The layer stack includes dielectric layers and sacrificial layers alternatingly stacked over each other. At Step S320, an epitaxial seed structure is formed that has a shape of comb handle extending through the layer stack from the substrate. At Step S330, the sacrificial layers are removed to uncover side portions of the epitaxial seed structure. At Step S340, semiconductor material is epitaxially grown from the side portions of the epitaxial seed structure to form a comb-shaped epitaxial structure.

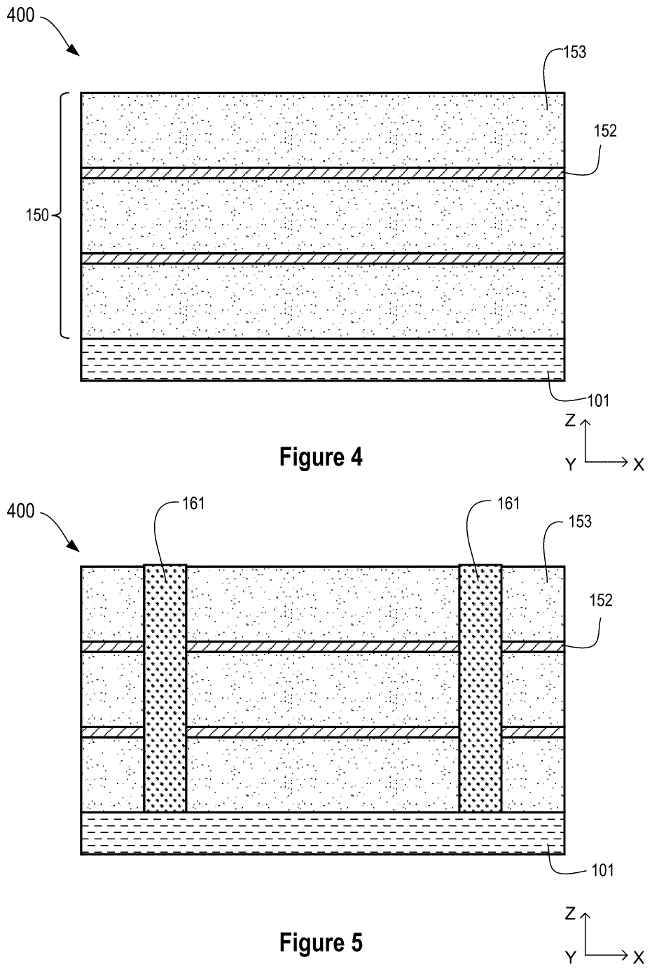

FIGS. 4, 5, 6, 7, 8, 9 and 10 show cross-sectional views of a semiconductor device 400 at various intermediate steps of manufacturing, in accordance with some embodiments of the present disclosure. A vertical epitaxial seed layer (having a shape of a comb handle) can be formed before a series of horizontal 3D nanosheets are grown in a dielectric tunnel, which results in a comb shape of single crystal epitaxial structure. The comb-handle-shaped seed layer can be removed to have a high density of 3D nanosheets arranged in the vertical direction.

As shown in FIG. 4, the semiconductor device 400 includes the substrate 101 and a layer stack 150 formed thereon. The layer stack 150 includes dielectric layers 153 and sacrificial layers 152 alternatingly stacked over each other in the Z direction. The sacrificial layers 152 may include dielectric material and be etch-selective relative to the dielectric layers 153.

In FIG. 5, epitaxial seed structures 161 are formed. The epitaxial seed structures each have a shape of a comb handle extending through the layer stack 150 from the substrate 101. For example, openings (e.g. holes, trenches, etc.) can be formed in the layer stack 150 to uncover atop surface of the substrate 101 before the epitaxial seed structures 161 are epitaxially grown from the top surface of the substrate 101 to fill the openings. The epitaxial seed structures can include intrinsic or doped semiconductor material.

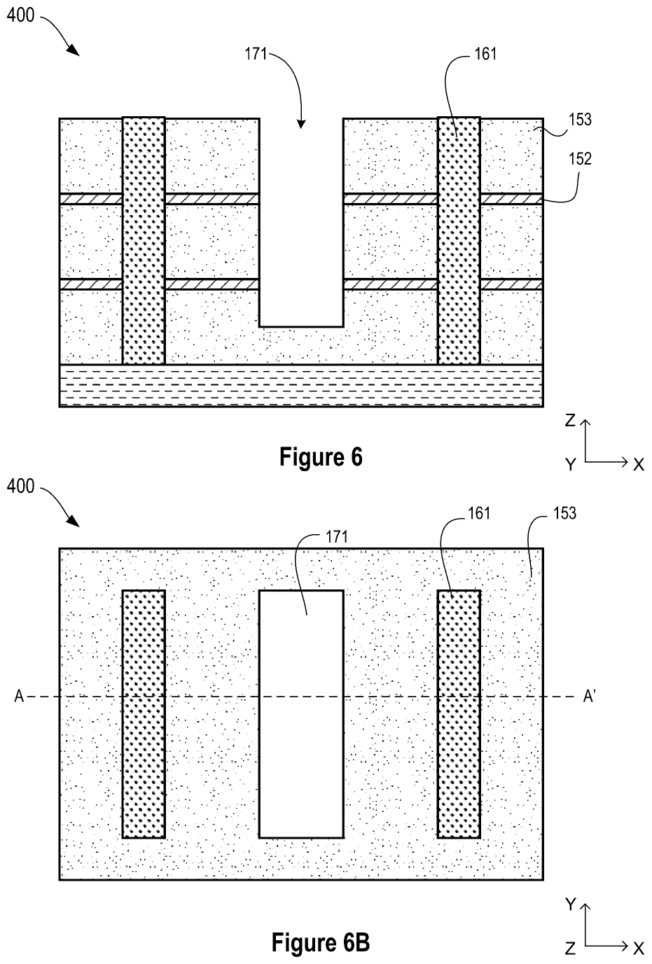

FIG. 6 is a cross-sectional view of the semiconductor device 400 taken along the line cut AA′ in FIG. 6B. In FIGS. 6 and 6B, an opening 171 is formed in the layer stack 150, which defines dimensions of future 3D nanosheets.

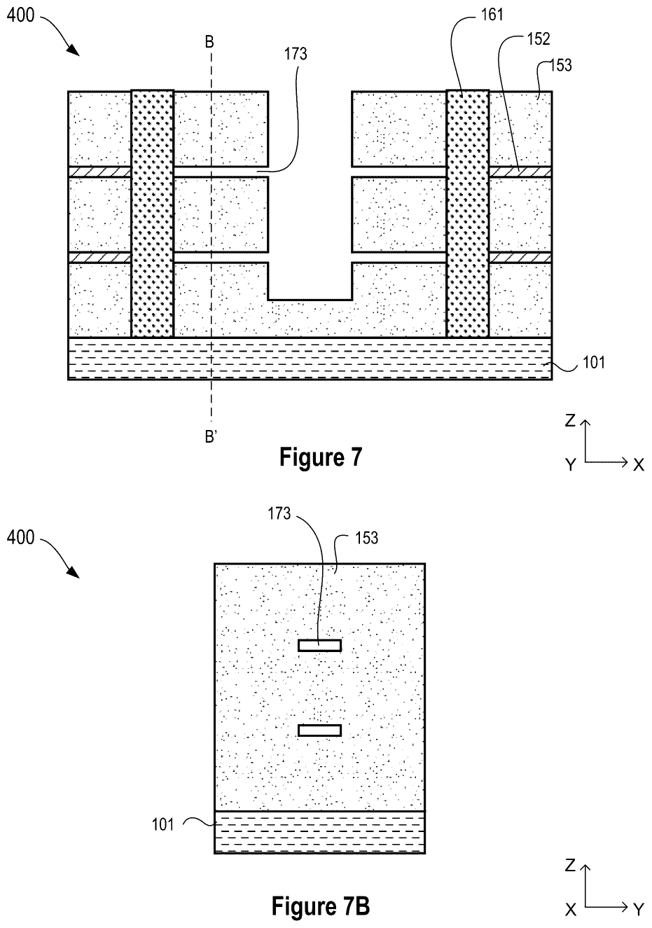

FIG. 7B is a cross-sectional view of the semiconductor device 400 taken along the line cut BB′ in FIG. 7. In FIGS. 7 and 7B, the sacrificial layers 152 are removed via the opening 171. As a result, gaps 173 (also referred to as tunnels or hollow tunnels) are formed between neighboring dielectric layers 153, and side portions of the epitaxial seed structures 161 are uncovered.

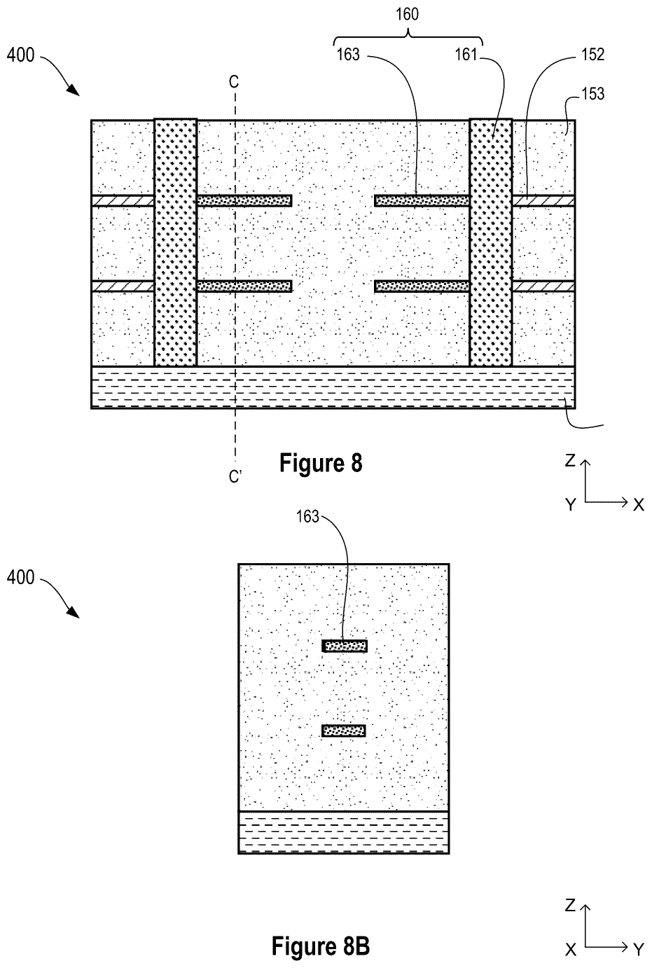

FIG. 8B is a cross-sectional view of the semiconductor device 400 taken along the line cut CC′ in FIG. 8. In FIGS. 8 and 8B, semiconductor material 163 is epitaxially grown from the side portions of the epitaxial seed structures 161 to form comb-shaped epitaxial structures 160. That is, each of the epitaxial seed structures 161 is a comb handle while the respective semiconductor material 163 is comb teeth.

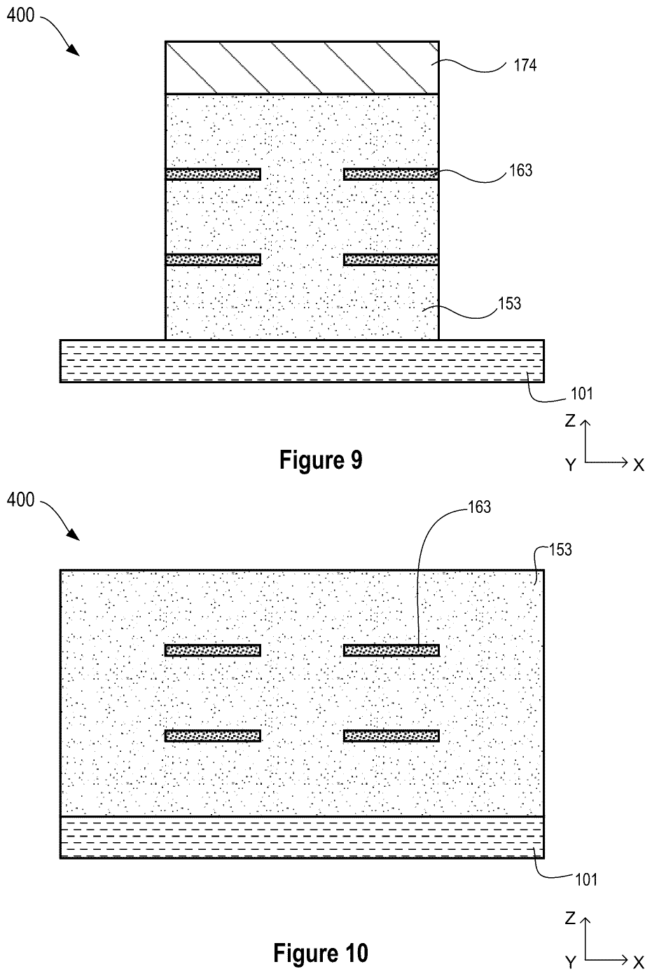

In FIG. 9, a patterned hard mask layer 174 can be used to remove the epitaxial seed structures 161, and optionally the (remaining) sacrificial layers 152.

In FIG. 10, the patterned hard mask layer 174 is removed, and the dielectric layer 153 is formed and planarized for example using chemical-mechanical polishing (CMP).

Note that FIGS. 4-10 are not drawn to scale. The semiconductor material 163 may have any shape, such as a horizontal nanosheet, a vertical nanosheet (e.g. the first channel structures 111), a bar, a wire, a rod, etc. depending on specific design needs. Regardless of the shape, the comb-shaped epitaxial structures 160 can have a comb shape in a vertical cross-sectional view, such as the cross-sectional view of FIG. 8.

In one example, the substrate 101 is a silicon substrate having a top surface of single crystal silicon. The epitaxial seed structures 161 include silicon. The semiconductor material 163 includes silicon. In another example, the substrate 101 is single crystal silicon. The epitaxial seed structures 161 include SiGe (e.g. Si_{0.8}Ge_{0.2} and Si_{0.5}Ge_{0.5}). The semiconductor material 163 includes Si_{0.6}Ge_{0.4} or Ge.

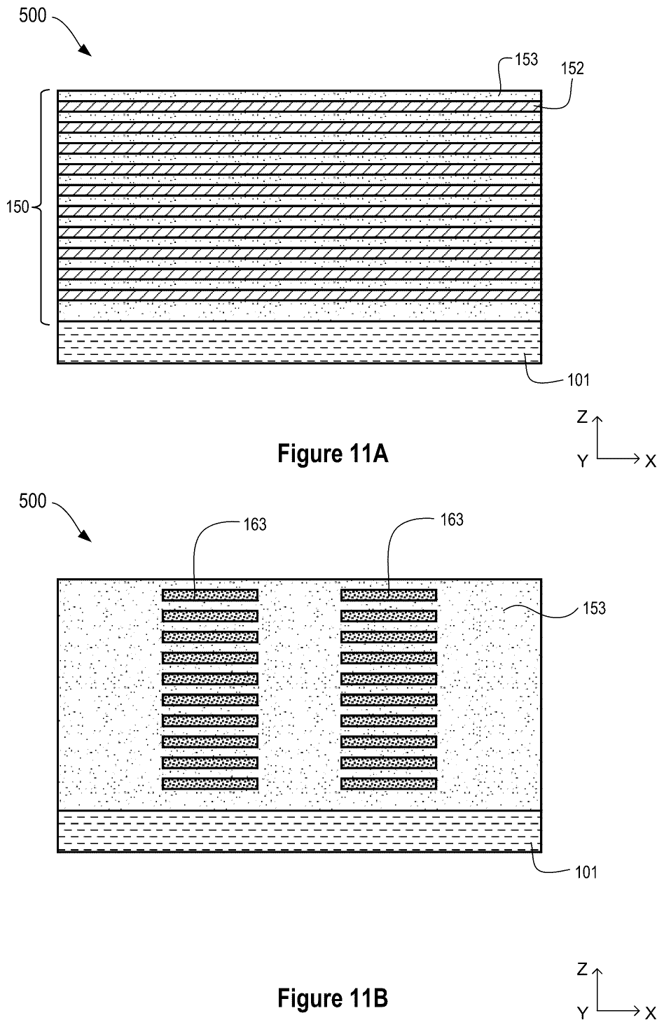

While only two comb teeth are formed for each comb handle in the examples of FIGS. 4-10, it should be understood that any number of comb teeth can be formed in other examples. For example, in FIG. 11A, the layer stack 150 of a semiconductor device 500 can have ten of the sacrificial layers 152 so ten comb teeth (e.g. the semiconductor material 163) can be formed in the Z direction in FIG. 11B by applying the same or similar processes shown in FIGS. 4-10.

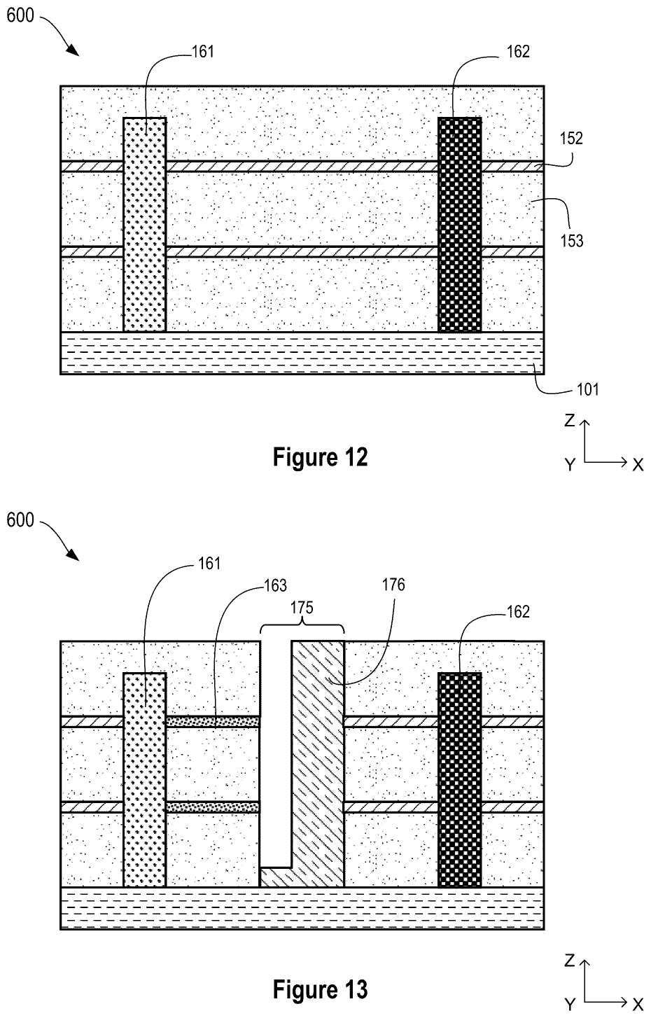

FIGS. 4, 12, 13, 14, 15, 16 and 17 show cross-sectional views of a semiconductor device 600 at various intermediate steps of manufacturing, in accordance with some embodiments of the present disclosure. Such a process may start with FIG. 4 and then proceeds to FIG. 12.

In FIG. 12, at least two epitaxial seed structures (e.g. 161 and 162) are formed in the layer stack 150. Accordingly, 161 and 162 will be respectively referred to as a first epitaxial seed structure 161 and a second epitaxial seed structure 162. The first epitaxial seed structure 161 and the second epitaxial seed structure 162 can be epitaxially grown from the substrate 101. For example, a first opening can be formed through the layer stack 150 to form the first epitaxial seed structure 161 before a second opening is formed through the layer stack 150 to form the second epitaxial seed structure 162. The dielectric layer 153 can then be formed on top as a capping layer. Alternatively, two openings can be formed through the layer stack 150 and filled with dielectric material. Then one opening is protected while the other is replaced with the first epitaxial seed structure 161. Subsequently, a capping layer (e.g. 153) can be formed on top. The first epitaxial seed structure 161 is then protected while the one opening is replaced with the second epitaxial seed structure 162.

In FIG. 13, an opening 175 is formed in the layer stack 150 and partially filled with dielectric material 176 to selectively uncover side portions of the sacrificial layers 152 which are then replaced with the semiconductor material 163 (will also be referred to as a first semiconductor material 163). For example, the opening 175 can be formed in the layer stack 150 and completely filled with the dielectric material 176. The dielectric material 176 is then directionally etched to uncover the side portions of the sacrificial layers 152 which are selectively etched away to form gaps (or tunnel regions) between neighboring dielectric layers 153 and uncover side portions of the first epitaxial seed structure 161. The first semiconductor material 163 is then epitaxial grown from the uncovered side portions of first epitaxial seed structure 161 to fill the gaps.

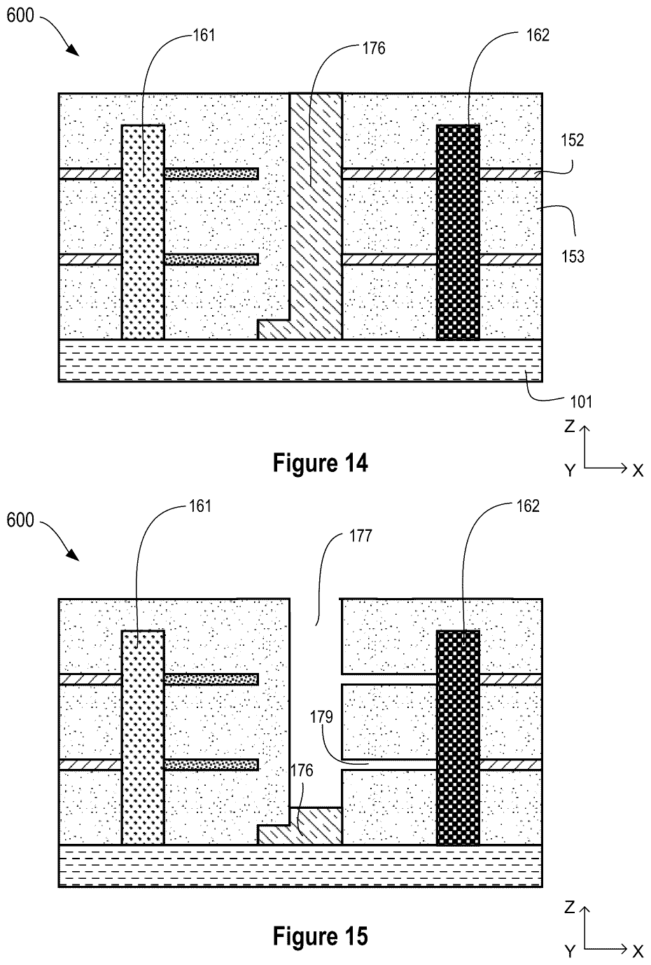

In FIG. 14, the opening 175 is filled with dielectric material, e.g. 153 in this example.

In FIG. 15, an opening 177 is formed by at least partially etching the dielectric material 176. Then gaps 179 are formed by selectively etching the sacrificial layer 152 to uncover side portions of the second epitaxial seed structure 162.

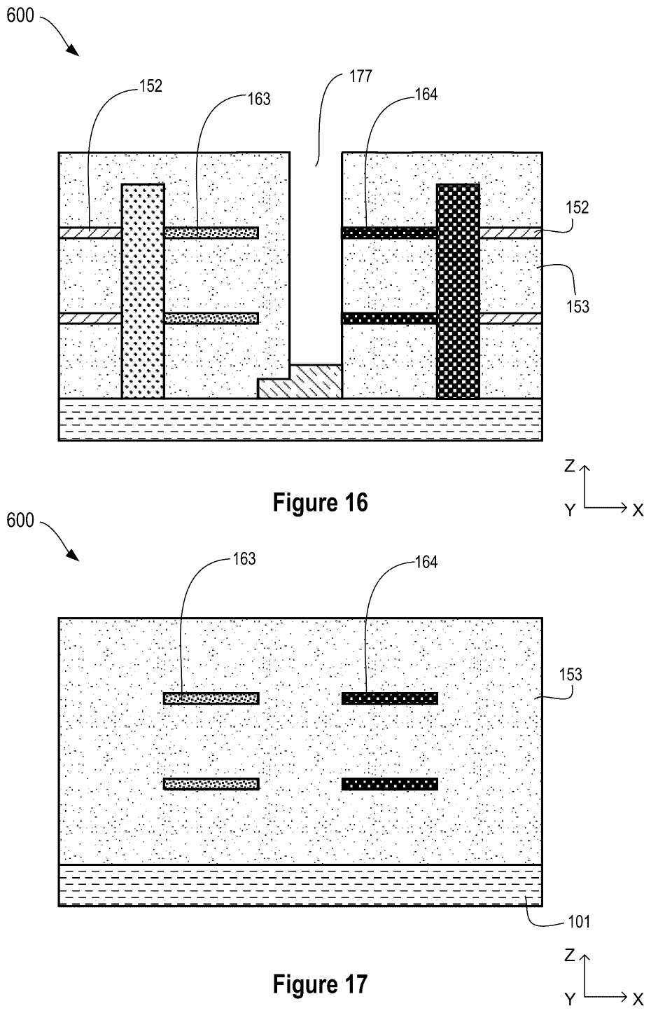

In FIG. 16, a second semiconductor material 164 is epitaxial grown from the uncovered side portions of the second epitaxial seed structure 162 to fill the gaps 179.

In FIG. 17, the opening 177 is filled with the dielectric layer 153, and the first epitaxial seed structure 161 and the second epitaxial seed structure 162 are removed. Note that the dielectric material 176 may be completely removed in this example.

In the example of FIGS. 12-17, the first semiconductor material 163 and the second semiconductor material 164 can include different chemical compositions from one another. That is, the channel structures can include different semiconductor materials, different dopants and/or different dopant concentration profiles. For instance, the first semiconductor material 163 and the second semiconductor material 164 can respectively include Si (e.g. NMOS channel) and Ge (e.g. PMOS channel). SiₓGe_{y} denotes SiGe material with a molar ratio of Si:Ge=x:y. When the substrate 101 includes a top surface of single crystal silicon, the second epitaxial seed structure 162 can have an intermediate chemical composition (e.g. Si_{0.5}Ge_{0.5}), relative to the substrate 101 (e.g. Si) and the second semiconductor material 164 (e.g. Ge). In another example, the first semiconductor material 163 and the second semiconductor material 164 can respectively include Si (e.g. NMOS channel) and SiGe (e.g. PMOS channel). When the second semiconductor material 164 is Si_{0.6}Ge_{0.4}, the second epitaxial seed structure 162 can be Si_{0.8}Ge_{0.2}. When the second semiconductor material 164 is Si_{0.2}Ge_{0.8}, the second epitaxial seed structure 162 can be Si_{0.6}Ge_{0.4}.

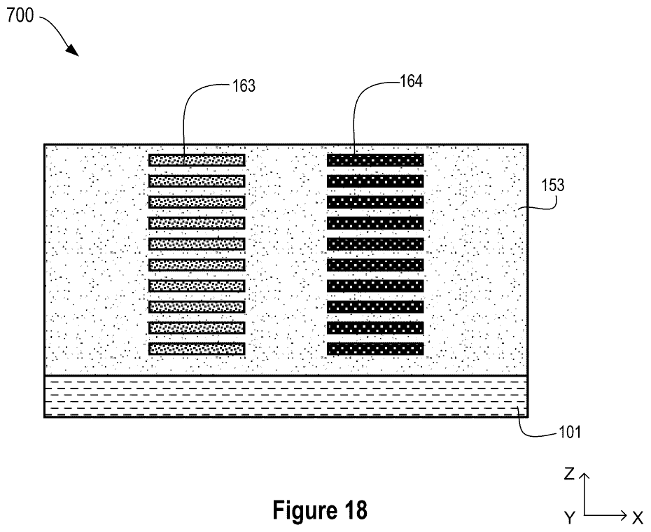

While only two comb teeth are formed for each comb handle in the examples of FIGS. 12-17, it should be understood that any number of comb teeth can be formed in other examples. For example in FIG. 18, ten comb teeth (e.g. the first semiconductor material 163 and the second semiconductor material 164) can be formed in the Z direction by applying the same or similar processes shown in FIGS. 12-17.

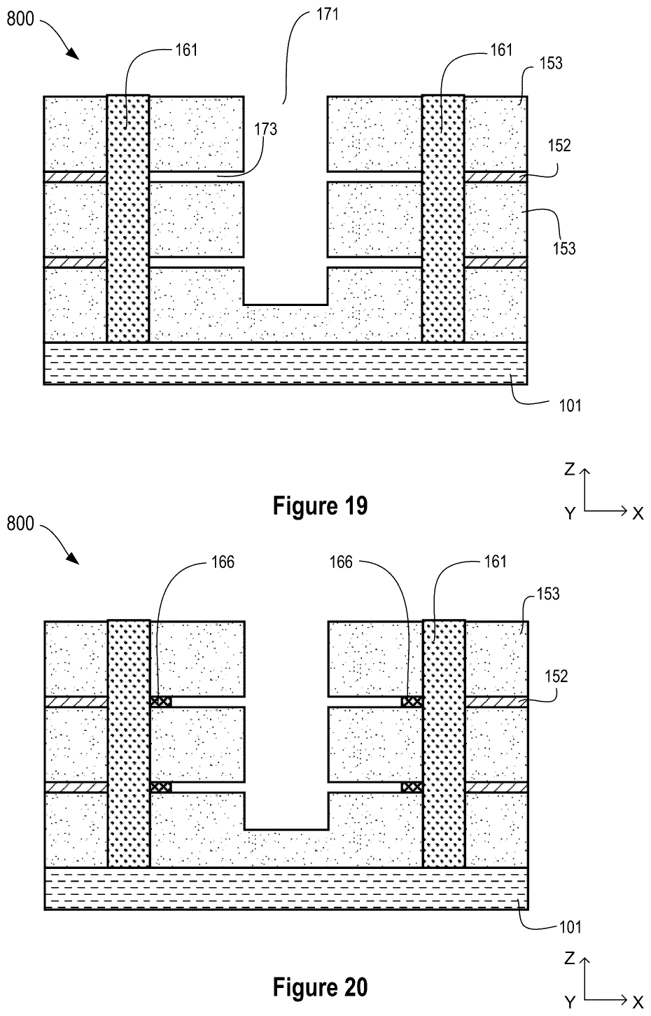

FIGS. 19, 20, 21 and 22 show cross-sectional views of a semiconductor device 800 at various intermediate steps of manufacturing, in accordance with some embodiments of the present disclosure. Particularly, the semiconductor device 800 in FIG. 19 can be obtained by the same or similar processes as the semiconductor device 400 in FIG. 7.

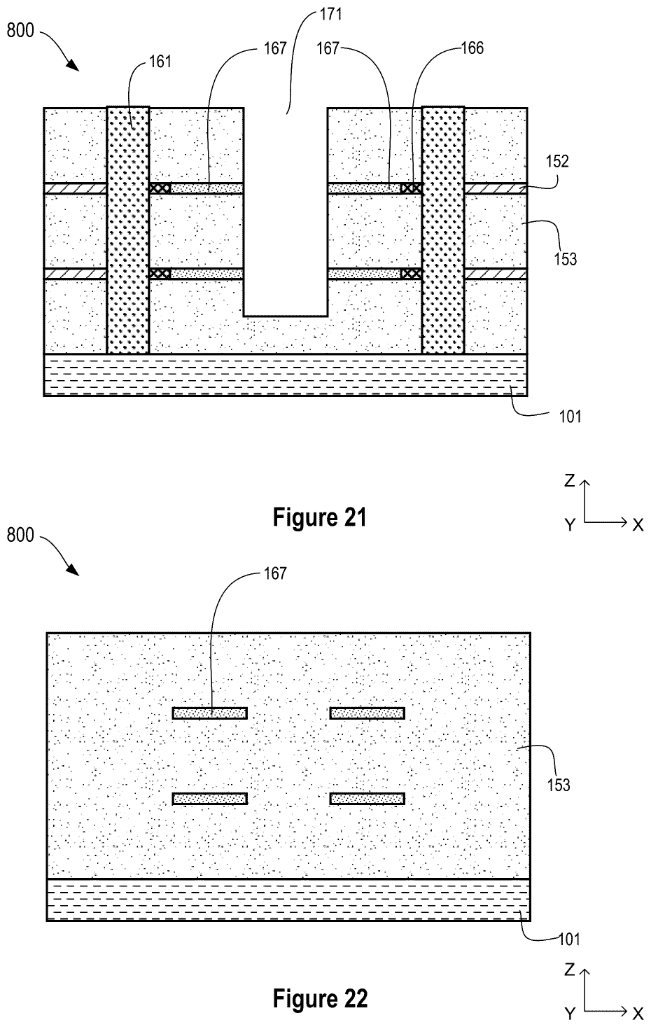

In FIG. 20, epitaxial transition structures 166 are epitaxially grown from the side portions of the epitaxial seed structures 161. In FIG. 21, a semiconductor material 167 is epitaxially grown from the epitaxial transition structures 166. In FIG. 22, the opening 171 is filled with the dielectric layer 153. The epitaxial seed structures 161 and the epitaxial transition structures 166 are removed. The dielectric layer 153 is deposited and planarized.

In some embodiments, the semiconductor material 167 can include InGaAs while the substrate 101 may include Si. Accordingly, the epitaxial seed structures 161 can include Si while the epitaxial transition structures 166 includes an intermediate chemical composition, relative to the epitaxial seed structures 161 and the semiconductor material 167, in order to avoid lattice mismatch and improve epitaxial growth. In one embodiment, the epitaxial transition structures 166 each have a uniform chemical composition (e.g. GaAs) within itself. In another embodiment, the epitaxial transition structures 166 each have a non-uniform chemical composition, for example a composition gradient gradually transitioning from Si to InGaAs along the X direction. That is, the epitaxial transition structures 166 each have a first chemical composition close to Si at one end close to the epitaxial seed structures 161 and a second chemical composition close to InGaAs at another end close to the semiconductor material 167. In yet another embodiment, the epitaxial seed structures 161 may function as an epitaxial transition, and the epitaxial transition structures 166 may not be needed. For instance, the epitaxial seed structures 161 may include a lower portion having a composition gradient gradually transitioning from Si to InGaAs along the Z direction. The lower portion is in direct contact with the substrate 101 and positioned below the semiconductor material 167. The epitaxial seed structures 161 also includes an upper portion above the bottom portion. The upper portion can include InGaAs or a composition close to InGaAs.

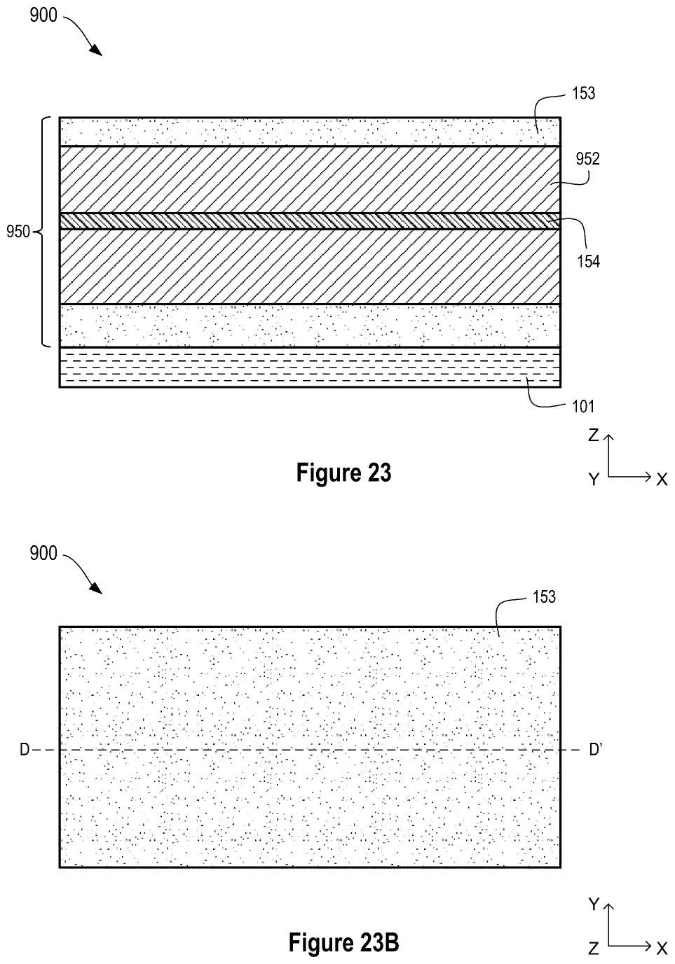

FIGS. 23, 24, 25, 26, 27, 28, 29, 30, 31, 32, 33, 34, 35, 36, 37, 38, 39, 40, 41 and 42 show cross-sectional views of a semiconductor device 900 at various intermediate steps of manufacturing, in accordance with some embodiments of the present disclosure. The semiconductor device 900 can eventually become the semiconductor device 100 in FIGS. 1A and 1B.

FIG. 23 shows a vertical cross-sectional view taken along the line cut DD′ in FIG. 23B. As shown, the semiconductor device 900 includes the substrate 101 and a layer stack 950 formed thereon. The layer stack 950 can include dielectric layers (e.g. 153 and 154) and sacrificial layers 952 alternatingly stacked over each other. The sacrificial layers 952 may include dielectric material and be etch-selective relative to the dielectric layers 153 and 154.

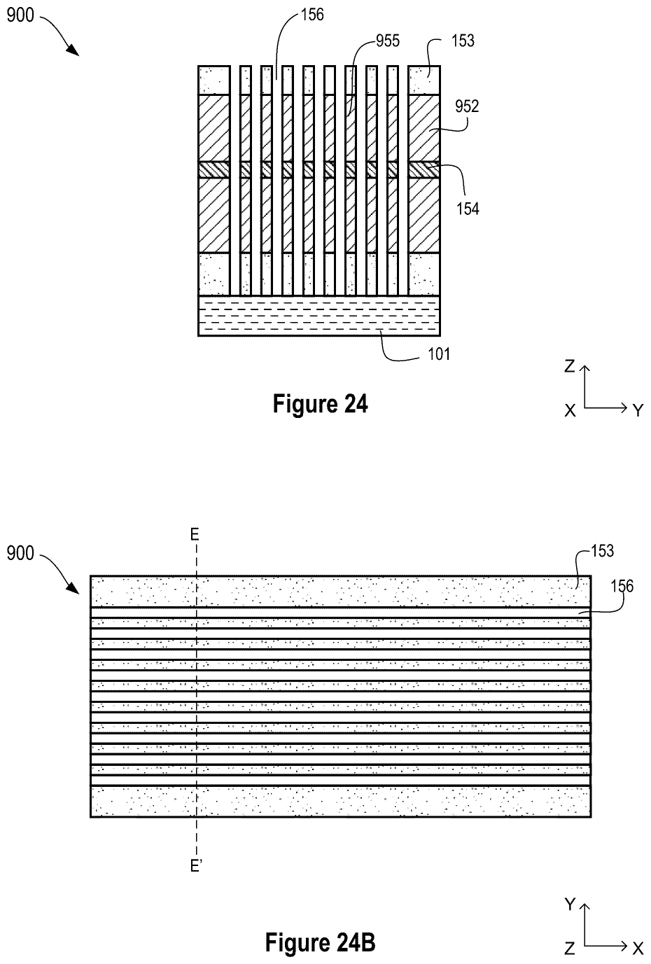

FIG. 24 shows a vertical cross-sectional view taken along the line cut EE′ in FIG. 24B. As shown, the layer stack 950 can be directionally etched to form individual nanosheets 955 of the sacrificial layers 952 which are spaced apart from one another in the Y direction and extend in the XZ plane. Specifically, the individual nanosheets 955 of the sacrificial layers 952 are separated from each other by gaps 156. Additionally, the individual nanosheets 955 can define the future small thin dimension of the p/2 rotated nanosheet, e.g. the third dimension of the first channel structures 111 in FIG. 1B.

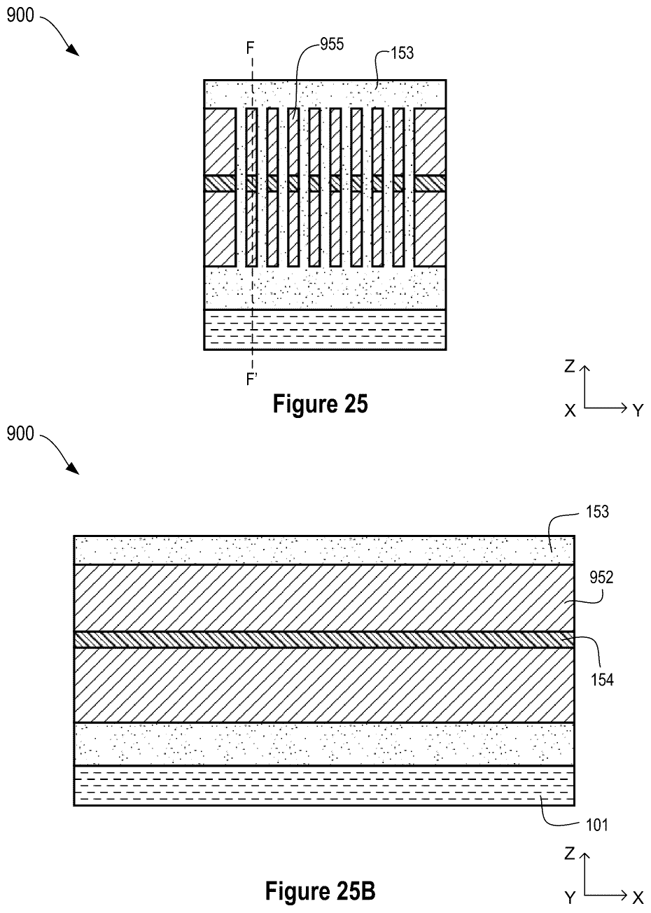

FIG. 25B shows a vertical cross-sectional view taken along the line cut FF′ in FIG. 25. As shown, isolation dielectric (e.g. the dielectric layers 153) can be deposited to fill the gaps 156 and planarized to form a capping layer on top.

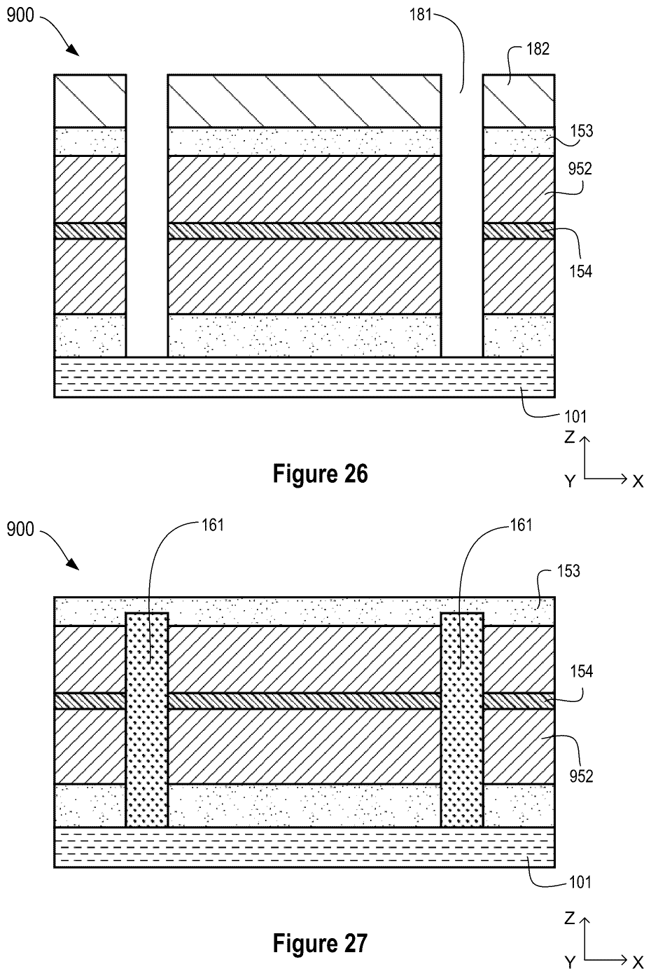

In FIG. 26, an etching mask 182 is used to form openings 181 through the layer stack 950 to uncover the substrate 101.

In FIG. 27, the epitaxial seed structures 161 are epitaxially grown from the substrate 101.

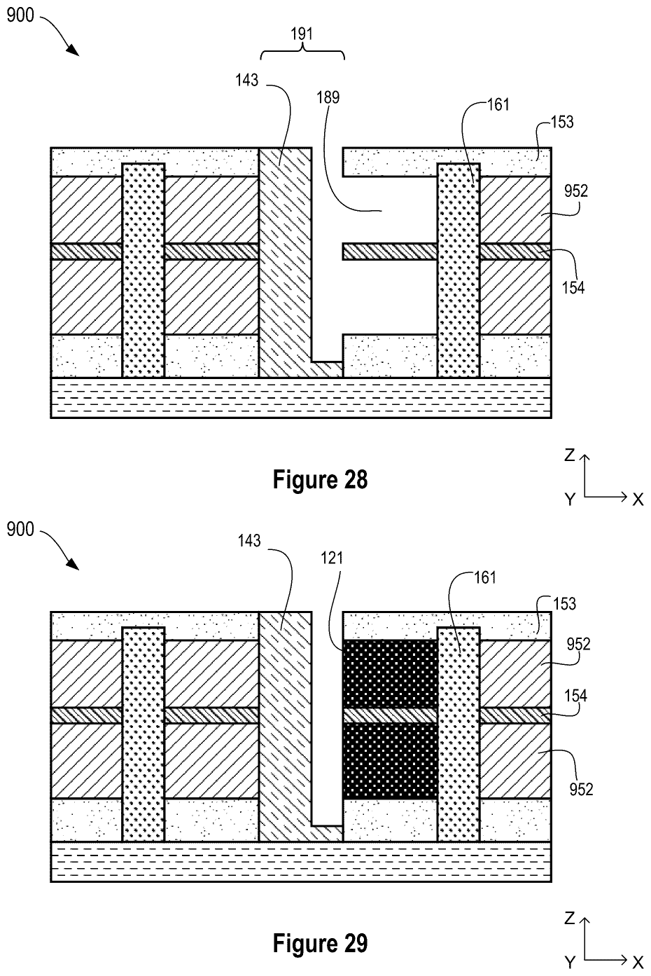

In FIG. 28, an opening 191 is formed in the layer stack 950 and partially filled with dielectric material 143. Gaps 189 (or tunnels) are formed by selectively etching the individual nanosheets 955 through the opening 191. As a result, side portions of the epitaxial seed structures 161 are uncovered.

In FIG. 29, the second channel structures 121 can be epitaxially grown from the side portions of the epitaxial seed structures 161 to fill the gaps 189.

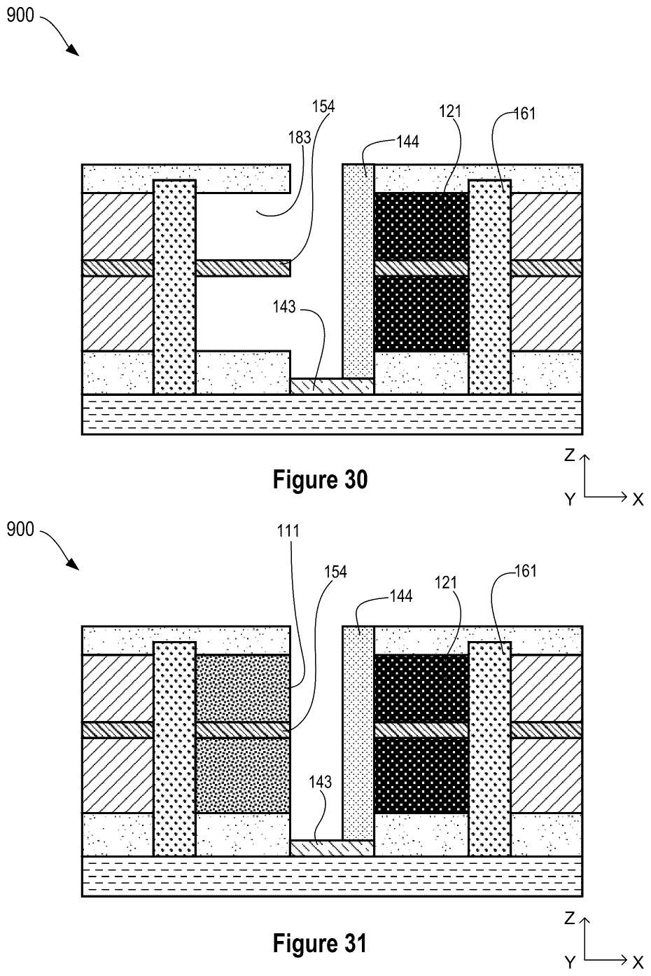

In FIG. 30, the opening 191 is filled with the dielectric material 144 and directionally etched before the individual nanosheets 955 are selectively etched to form gaps 183 and uncover side portions of the epitaxial seed structures 161.

In FIG. 31, the first channel structures 111 can be epitaxially grown from the side portions of the epitaxial seed structures 161 to fill the gaps 183.

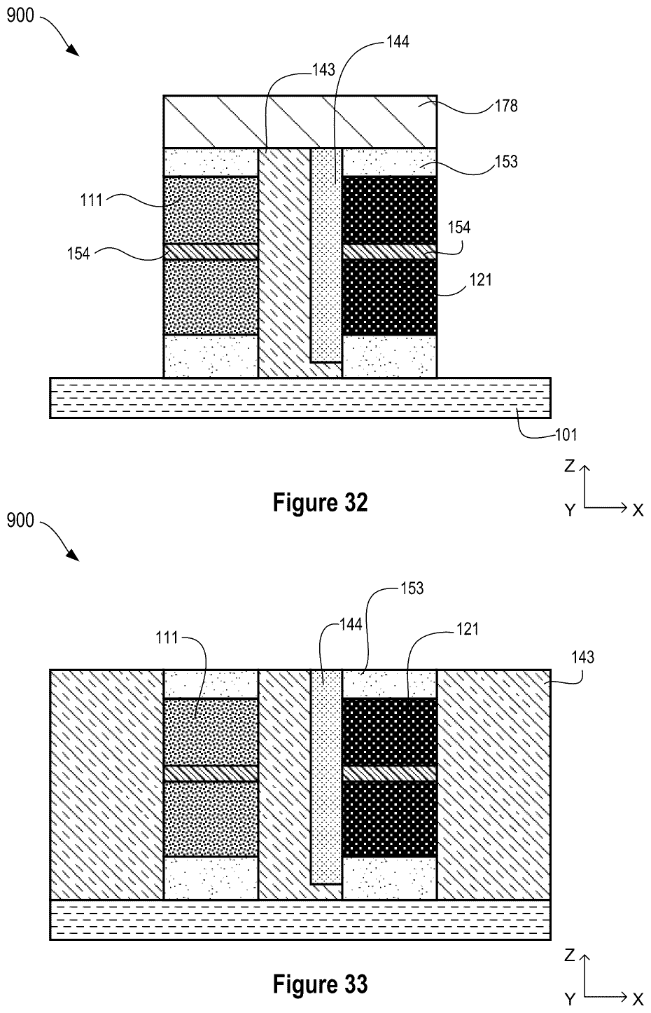

In FIG. 32, the opening 191 is filled with the dielectric material 143. The epitaxial seed structures 161 and the (remaining) sacrificial layers 952 are directionally etched using an etching mask 178.

In FIG. 33, the etching mask 178 is removed. The dielectric material 143 is deposited and planarized by CMP.

FIG. 34 shows a vertical cross-sectional view taken along the line cut GG′ in FIG. 34B. As shown, a hardmask layer 187 is formed and used to directionally etch the aforementioned isolation dielectric (e.g. dielectric layer 153) in front of and behind the first channel structures 111 to uncover the first channel structures 111 from opposite sides along the Y direction.

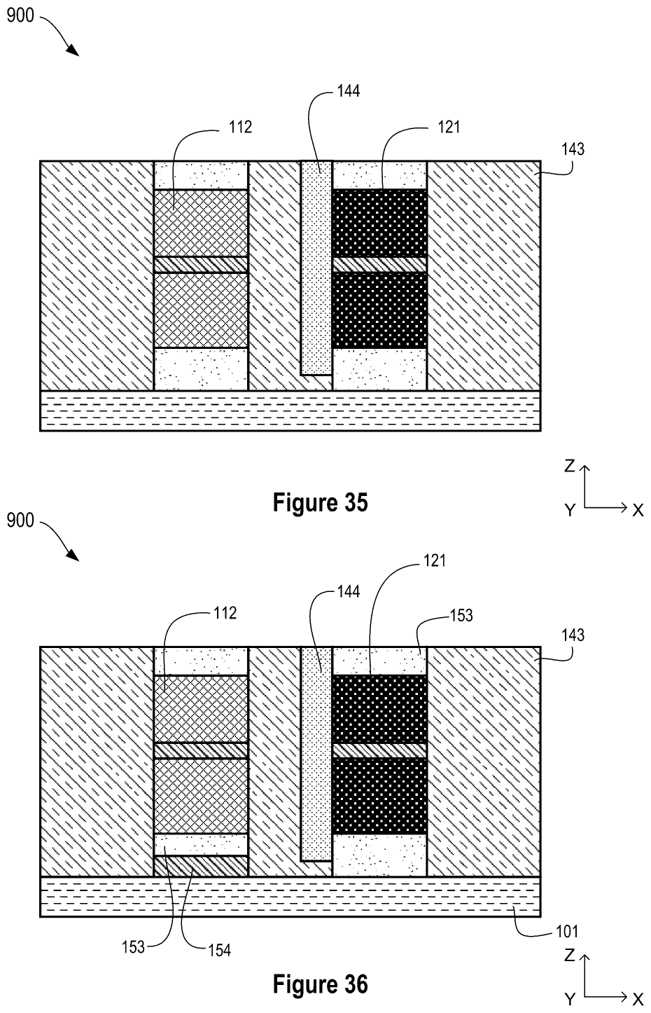

In FIG. 35, a gate dielectric 112 is formed over the first channel structures 111, which can be accomplished by selective deposition or non-selective deposition.

In FIG. 36, the dielectric material 154 is formed on the substrate 101, which will avoid future metal from shorting to the substrate 101.

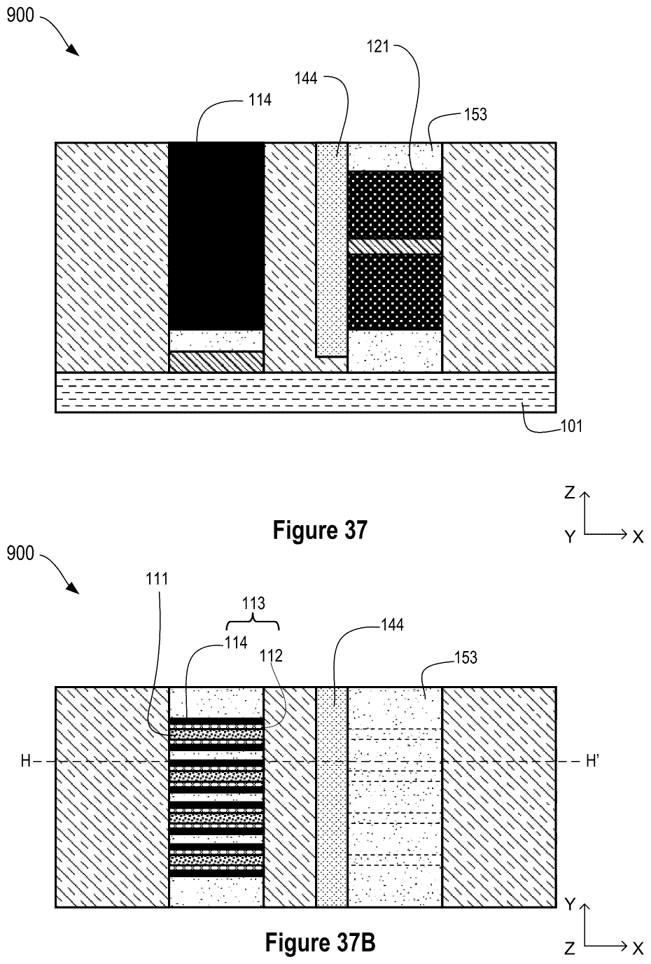

FIG. 37 shows a vertical cross-sectional view taken along the line cut HH′ in FIG. 37B. As shown, a gate metal 114 is formed over the gate dielectric 112, optionally followed by deposition of dielectric material (e.g. 153 or 154). As a result, the first gate structure 113 is formed and separated from the substrate 101 by the dielectric material 154.

FIG. 38 shows a vertical cross-sectional view taken along the line cut JJ′ in FIG. 38B. For illustrative purposes, the dielectric material 145 and an etching mask 192 are omitted. As shown, openings 191 are formed on opposing sides of the first channel structures 111 along the X direction.

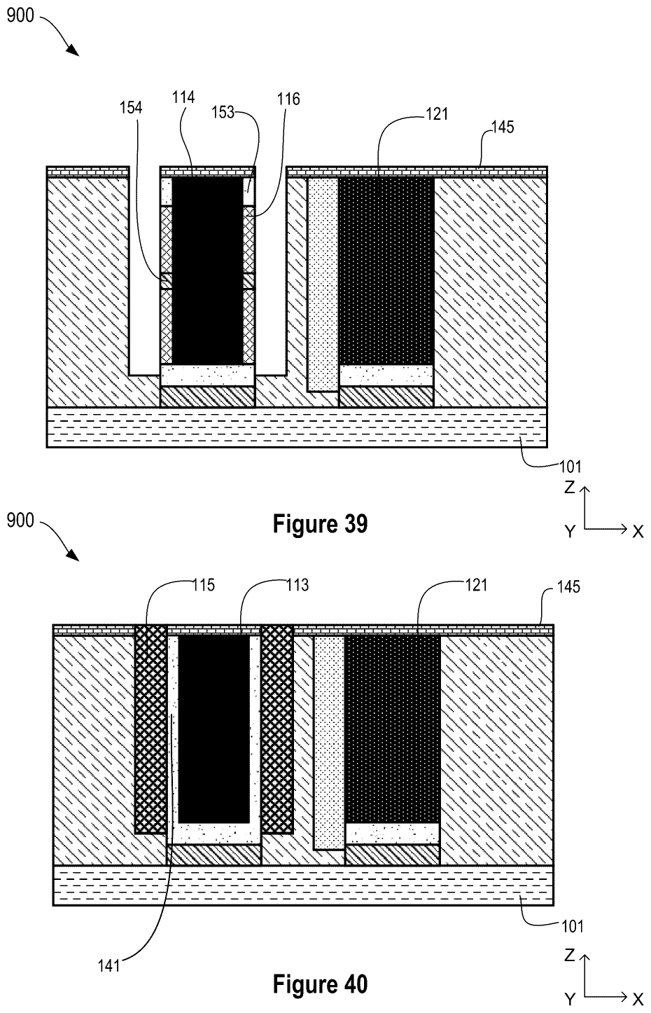

In FIG. 39, the first gate structures 113 are recessed in the X direction. For example, the gate dielectric 112 and/or the gate metal 114 can be recessed to define future S/D regions (e.g. 116). The first channel structures 111 can be doped (e.g. by plasma doping) around recessed areas to define S/D regions. A silicide may be formed before gate metal is deposited.

In FIG. 40, inner spacers (e.g. the dielectric material 141) can be formed in the S/D regions 116 (or the corresponding recesses), and the first S/D structures 115 can be formed to fill the openings 191. Herein, the first S/D structures 115 and the first gate structures 113 are separated by the inner spacers (e.g. the dielectric material 141).

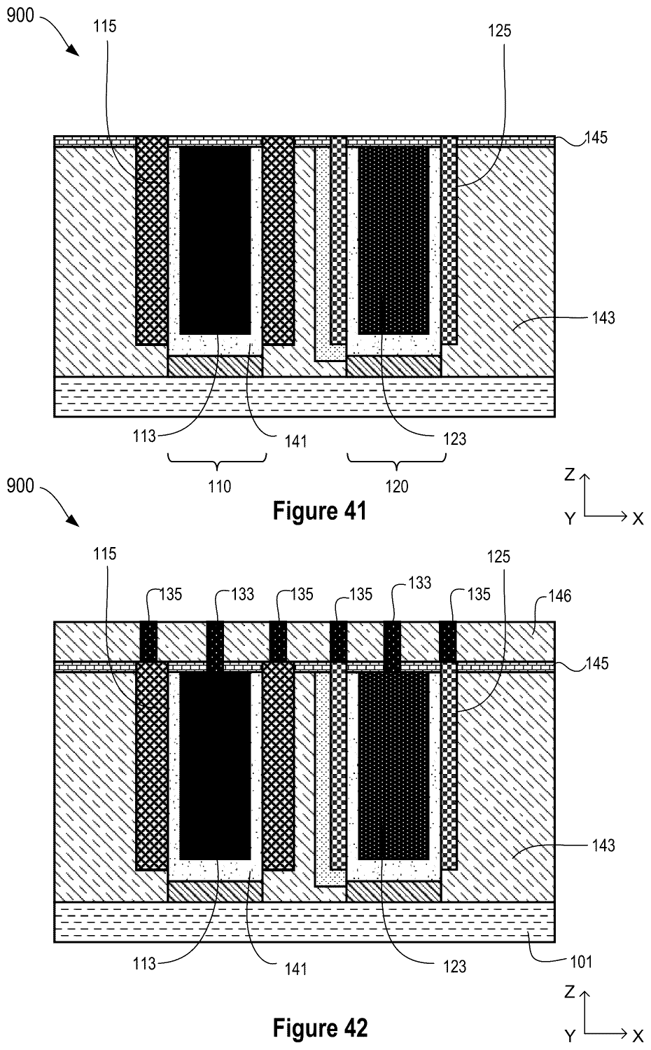

In FIG. 41, the second gate structures 123 and the second S/D structures 125 are formed, for example by processes similar to those disclosed in FIGS. 33-40. As a result, the first transistor 110 and the second transistor 120 are formed.

In FIG. 42, the dielectric material 146 is formed, and the contact structures 135 and 133 are formed. As a result, the semiconductor device 900 can become the semiconductor device 100.

In the example of FIGS. 23-42, the first channel structures 111 and the second channel structures 121 can include different chemical compositions from one another. That is, the channel structures can include different semiconductor materials, different dopants and/or different dopant concentration profiles. For instance, the first channel structures 111 and the second channel structures 121 can respectively include Si (e.g. NMOS channel) and SiGe (e.g. PMOS channel).

In some embodiments, the gate structures (e.g. 113 and 123) each include at least one gate dielectric (e.g. 112), such as a high-k dielectric, and at least one gate metal (e.g. 114), such as a work function metal (WFM). As can be appreciated, the gate metals (e.g. 114) which function as the gate conductors may be the same as or different from each other, and the gate dielectrics (e.g. 112) may also be the same as or different from each other, depending on respective channel structures (i.e. 111 and 121), design requirements (e.g. gate threshold voltage), etc. While the gate metals (e.g. 114) are shown as a single material, the gate metals (e.g. 114) may each be made up of two or more layers of metals having different work functions. Similarly, the gate dielectrics (e.g. 112) may be made up of two or more layers of dielectric materials.

Of course it should be understood that the semiconductor device 900 can include any number of transistors, such as the first transistor 110, the second transistor 120 and the like, arranged in the XY plane over the substrate 101. The first transistor 110 can include any number of the first channel structures 111 arranged in the Z direction.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “wafer” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

The substrate can be any suitable substrate, such as a silicon (Si) substrate, a germanium (Ge) substrate, a silicon-germanium (SiGe) substrate, and/or a silicon-on-insulator (SOI) substrate. The substrate may include a semiconductor material, for example, a Group IV semiconductor, a Group III-V compound semiconductor, or a Group II-VI oxide semiconductor. The Group IV semiconductor may include Si, Ge, or SiGe. The substrate may be a bulk wafer or an epitaxial layer.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A semiconductor device, comprising:
a substrate;
channel structures stacked over each other along a first direction substantially perpendicular to a working surface of the substrate and each configured to have a current direction along a second direction substantially parallel to the working surface of the substrate;
source/drain (S/D) structures on opposing sides of the channel structure along the second direction; and
gate structures on opposite sides of the channel structures along a third direction substantially parallel to the working surface of the substrate, wherein
the channel structures each have a shape of a nanosheet extending substantially perpendicular to the working surface of the substrate.

2. The semiconductor device of claim 1, wherein:
the nanosheet has a first dimension of 1-15 nm in the first direction,
the nanosheet has a second dimension of 1-15 nm in the second direction, and
the nanosheet has a third dimension of 0.1-3.0 nm in the third direction.

3. The semiconductor device of claim 2, wherein:
a first ratio of the third dimension to the first dimension is 0.05-0.3, and
a second ratio of the third dimension to the second dimension is 0.05-0.3.

4. The semiconductor device of claim 1, wherein:
the channel structures comprise epitaxially grown semiconductor material.

5. The semiconductor device of claim 1, wherein:
the channel structures are separated from each other only by dielectric material and not by metal material in the first direction.

6. The semiconductor device of claim 1, wherein:
the gate structures include two separate gate structures on the opposite sides of the channel structures along the third direction.

7. The semiconductor device of claim 6, wherein:
the two separate gate structures each are configured to be electrically connected to the channel structures.

8. The semiconductor device of claim 1, wherein:
the substrate has a top surface of monocrystalline semiconductor material.

9. A method of manufacturing a semiconductor device, the method comprising:
forming channel structures over a substrate, wherein the channel structures are stacked over each other along a first direction substantially perpendicular to a working surface of the substrate and each configured to have a current direction along a second direction substantially parallel to the working surface of the substrate, and the channel structures each have a shape of a nanosheet extending substantially perpendicular to the working surface of the substrate;
forming source/drain (S/D) structures on opposing sides of the channel structure along the second direction; and
forming gate structures on opposite sides of the channel structures along a third direction substantially parallel to the working surface of the substrate.

10. The method of claim 9, further comprising:
forming a layer stack over the substrate, the layer stack including dielectric layers and sacrificial layers alternatingly stacked over each other; and
directionally etching the sacrificial layers to form individual nanosheets that are spaced apart from one another in the third direction and extend substantially perpendicular to the working surface of the substrate.

11. The method of claim 10, further comprising:
forming an epitaxial seed structure extending through the layer stack from the substrate;
removing the individual nanosheets to uncover side portions of the epitaxial seed structure; and
epitaxially growing semiconductor material from the side portions of the epitaxial seed structure to form the channel structures.

12. The method of claim 11, wherein:
the substrate has a top surface comprising monocrystalline semiconductor material.

13. The method of claim 12, further comprising:
forming an opening through the layer stack, the opening uncovering the top surface of the substrate; and
epitaxially growing the epitaxial seed structure from the top surface of the substrate to fill the opening.

14. The method of claim 11, further comprising:
forming an opening in the layer stack, the opening uncovering side portions of the individual nanosheets;
selectively etching the individual nanosheets to form gaps between neighboring dielectric layers, the gaps uncovering the side portions of the epitaxial seed structure; and
filling the gaps with the semiconductor material.

15. The method of claim 10, further comprising:
forming a first epitaxial seed structure and a second epitaxial seed structure both extending through the layer stack from the substrate;
forming an opening in the layer stack between the first epitaxial seed structure and the second epitaxial seed structure, the opening dividing the individual nanosheets into first nanosheets and second nanosheets;
replacing the first nanosheets with a first semiconductor material connected to the first epitaxial seed structure; and
replacing the second nanosheets with a second semiconductor material connected to the second epitaxial seed structure.

16. A method of manufacturing a semiconductor device, the method comprising:
forming a layer stack over a substrate, the layer stack including dielectric layers and sacrificial layers alternatingly stacked over each other;
forming an epitaxial seed structure that has a shape of comb handle extending through the layer stack from the substrate;
removing the sacrificial layers to uncover side portions of the epitaxial seed structure; and
epitaxially growing semiconductor material from the side portions of the epitaxial seed structure to form a comb-shaped epitaxial structure.

17. The method of claim 16, wherein:
the substrate has a top surface comprising monocrystalline semiconductor material.

18. The method of claim 17, further comprising:
forming an opening in the layer stack, the opening uncovering the top surface of the substrate; and
epitaxially growing the epitaxial seed structure from the top surface of the substrate to fill the opening.

19. The method of claim 16, further comprising:
forming an opening in the layer stack, the opening uncovering side portions of the sacrificial layers;
selectively etching the sacrificial layers to form gaps between neighboring dielectric layers, the gaps uncovering the side portions of the epitaxial seed structure; and
filling the gaps with the semiconductor material.

20. The method of claim 16, wherein the epitaxially growing the semiconductor material from the side portions of the epitaxial seed structure comprises:
epitaxially growing an epitaxial transition structure from the side portions of the epitaxial seed structure; and
epitaxially growing the semiconductor material from the epitaxial transition structure.
